(19) United States
(12) Patent Application Publication
(10) Pub. No.: US 2006/0038266 A1
(43) Pub. Date: Feb. 23, 2006

(54) QFN package and method therefor

(76) Inventors: Fu-Bin Song, Tianjin (CN); Yan-Feng Liu, Tianjin (CN); Zhi-Jie Wang, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/955,359

(22) Filed: Sep. 30, 2004

(30) Foreign Application Priority Data
Aug. 17, 2004 (CN) 200410057520.2

(51) Int. Cl. H01L 23/495

(52) U.S. Cl. 257/676

(57) ABSTRACT

A semiconductor device (20) includes an integrated circuit (22) having a plurality of bonding pads (24) located on a peripheral portion of its top surface and a groove (26) formed in its bottom surface (28). The groove (26) extends from one end to an opposite end of the IC (22). Lead fingers (30) that surround the IC (22) are electrically connected to respective ones of the bonding pads (24) via wirebonding. A mold compound (34) covers the top surfaces of the IC (22) and the lead fingers (30), and the electrical connections. At least the bottom surfaces of the lead fingers (30) and the IC (22) are exposed, except for the groove (26), which is filled with the mold compound (34).

### BACKGROUND OF THE INVENTION

The present invention relates to integrated circuits and packaged integrated circuits and, more particularly, to a packaged integrated circuit where the die is exposed.

An integrated circuit (IC) die is a small device formed on a semiconductor wafer, such as a silicon wafer. A leadframe is a metal frame that usually includes a paddle that supports an IC die that has been cut from the wafer. The leadframe has lead fingers that provide external electrical connections. That is, the die is attached to the die paddle and then bonding pads of the die are connected to the lead fingers via wire bonding or flip chip bumping to provide the external electrical connections. Encapsulating the die and wire bonds or flip chip bumps with a protective material, such as a mold compound forms a package. Depending on the package type, the external electrical connections may be used as-is, such as in a Thin Small Outline Package (TSOP) or quad-flat no-lead (QFN), or further processed, such as by attaching spherical solder balls for a Ball Grid Array (BGA). These terminal points allow the die to be electrically connected with other circuits, such as on a printed circuit board.

Some leadframes do not include a die paddle, rather, the die back is exposed, which allows heat to dissipate and the package to have a lower profile. FIG. 1 is a top plan view of a conventional exposed die type QFN packaged device 10. The device 10 includes a die 12 and lead fingers 14 around the package perimeter. The lead fingers 14 are exposed on the bottom and side surfaces of the device 10. FIG. 2 is a side cross-sectional view of the QFN device 10. As can be seen, bonding pads on a top side of the die 12 are electrically connected to the lead fingers 14 with wires 16. The top and sides of the die 12, the top and one side of the lead fingers 14, and the wires 16 are covered with a plastic material or mold compound 18. Note that the bottom of the die 12 and the bottoms and outer sides of the lead fingers 14 are exposed. When the die 12 is exposed, there is a risk that the die 12 may become separated from the mold compound 18, which could compromise the planarity of the device bottom and/or the electrical connections between the die 12 and the lead fingers 14. Thus, it would be desirable to reduce or eliminate the risk of the die 12 becoming separated from the mold compound 18.

### BRIEF DESCRIPTION OF THE DRAWINGS

The following detailed description of a preferred embodiment of the invention, will be better understood when read in conjunction with the appended drawings. For the purpose of illustrating the invention, there is shown in the drawings an embodiment that is presently preferred. It should be understood, however, that the invention is not limited to the precise arrangement and instrumentalities shown. In the drawings:

FIG. 1 is an enlarged, bottom plan view of a conventional QFN type packaged device;

FIG. 2 is an enlarged, side cross-sectional view of the QFN device of FIG. 1;

FIG. 3 is an enlarged, side cross-sectional view of a QFN type packaged device in accordance with an embodiment of the present invention;

FIG. 4 is an enlarged bottom plan view of the QFN device of FIG. 3; and

FIGS. 5-10 show various steps of forming the QFN device of FIG. 3.

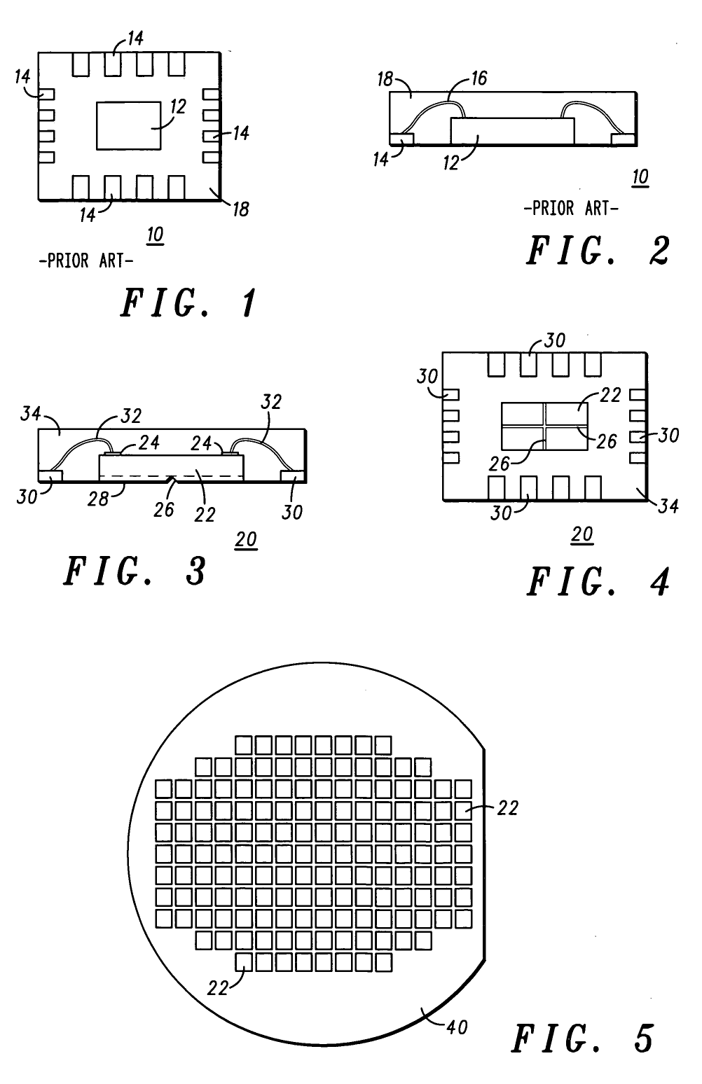

### DETAILED DESCRIPTION OF PREFERRED EMBODIMENTS

The detailed description set forth below in connection with the appended drawings is intended as a description of the presently preferred embodiment of the invention, and is not intended to represent the only form in which the present invention may be practiced. It is to be understood that the same or equivalent functions may be accomplished by different embodiments that are intended to be encompassed within the spirit and scope of the invention. As will be understood by those of skill in the art, the present invention can be applied to various packages and package types.

Certain features in the drawings have been enlarged for ease of illustration and the drawings and the elements thereof are not necessarily in proper proportion. Further, the invention is shown embodied in a Quad Flat No-lead (QFN) type package. However, those of ordinary skill in the art will readily understand the details of the invention and that the invention is applicable to other package types. In the drawings, like numerals are used to indicate like elements throughout.

The present invention is a semiconductor device including an integrated circuit (IC) having a plurality of bonding pads located on a peripheral portion of a first surface thereof and a groove formed in a second surface thereof. The groove extends from one end of the IC to an opposite end of the IC. The IC is surrounded by a plurality of lead fingers. A plurality of wires connect the IC bonding pads with respective ones of the plurality of lead fingers. A mold compound covers the first surface of the IC, the plurality of wires, and a portion of the plurality of lead fingers. At least bottom surfaces of the leads fingers and the second surface of the IC are exposed. The groove is filled with the mold compound. Providing the groove and filling it with the mold compound inhibits separation of the IC from the mold compound.

The present invention further provides a method of packaging a semiconductor device comprising the steps of:

providing a wafer having a plurality of integrated circuits (ICs) formed on a first surface thereof, wherein the ICs have a top surface with a plurality of bonding pads and a bottom surface;

forming a plurality of grooves in a second surface of the wafer such that each of the ICs has at least one groove extending along a bottom surface thereof;

separating the ICs from each other;

providing a leadframe panel having a plurality of leadframes, each of the leadframes having a plurality of lead fingers formed around a die receiving area;

applying a tape to a first side of the leadframe panel;

attaching the bottom surfaces of the separated ICs to the tape in respective ones of the die receiving areas;

electrically connecting the IC bonding pads with respective ones of the lead fingers;

forming a mold compound over at least a second surface of the leadframe panel such that the mold compound covers the top surface of the IC, the electrical connections, and the second side of the lead fingers;

injecting the mold compound into the grooves in the bottom surfaces of the ICs;

removing the tape from the first side of the lead frame panel such that the first sides of the lead fingers and the bottom sides of the ICs are exposed. Additionally, the method may include the step of separating the leadframes from each other.

Referring now to FIG. 3, an enlarged, side cross-sectional view of a QFN type packaged device 20 in accordance with an embodiment of the present invention is shown. The packaged device 20 includes an integrated circuit (IC) 22. The integrated circuit 22 may be of a type known to those of skill in the art, such as a circuit formed on and cut from a silicon wafer. Typical circuit (die) sizes may range from 2 mm×2 mm to 12 mm×12 mm and have a thickness ranging from about 3 mils to about 21 mils. The packaged device 20 is known as a QFN (Quad Flat No-Lead) package and may range in size from about 3×3 mm to about 16×16 mm. However, it will be understood by those of skill in the art that the circuit and package sizes may vary and that the shape of the packaged device may vary too.

The IC 22 has a plurality of bonding pads 24 that allow signals to be input to and received from the IC 22. In the embodiment shown, the bonding pads are located on a peripheral portion of a top or first surface of the IC 22. The IC 22 also has at least one groove 26 formed in a bottom or second surface 28 thereof. The QFN device 20 is an exposed die type device, which means that the bottom surface 28 of the IC 22 is exposed. A plurality of lead fingers 30 surrounds the IC 22. The lead fingers 30 are connected to respective ones of the IC bonding pads 24 with a corresponding plurality of wires 32. The wires 32 are connected to the bonding pads 24 and the lead fingers 30 using known a known wire bonding process. The lead fingers 30 are formed of a metal or metal alloy and have a predetermined thickness. For example, the lead fingers 30 may comprise copper that is pre-plated with tin. The wires 32 also are of a type well known to those of skill in the art and typically are formed of copper or gold.

A mold compound 34 covers the first surface of the IC 22, the plurality of wires 32, and a portion of the plurality of lead fingers 30, with at least the bottom surfaces of the lead fingers 30 and the bottom surface 28 of the IC 22 are exposed. The outer sides of the lead fingers 30 also may be exposed. In order to aid in securing the IC 22, the groove 26 is filled with the mold compound 34.

FIG. 4 is a bottom plan view of the QFN device 10, showing the bottom side 28 of the packaged device 10. As can be seen, the lead fingers 30 surround the IC 22. In one embodiment of the invention, the groove 26 includes two grooves that extend from one end of the IC 22 to an opposite end of the IC 22 with the two grooves being perpendicular to each other and intersecting near a center of the IC 22. However, the groove 26 could take other forms, such as two parallel grooves. The function of the groove 26 is to allow mold compound to extend under the IC 22 in order to inhibit the IC 22 from separating from the mold compound 34. Separation of the IC 22 from the mold compound 34 can adversely affect the quality of the packaged device 10, such as by weakening the wirebonds or degrading the planarity of the bottom of the device 10.

Referring now to FIGS. 3 and 4, the groove 26 may have a depth that is sufficient for allowing the mold compound to flow therethrough and support the IC 22. In the drawings, the groove 26 has a depth that is somewhat less than a thickness of the lead fingers 30. For example, for an IC 22 that has a thickness of about 11 mils, the groove 26 may have a depth of about 3 mils. The groove 26 should not be too deep such that the wafer or IC could crack or break. The groove 26 may be formed in the bottom surface 28 of the IC 22 by cutting, for example, using a V-shaped saw blade, which forms an inverted V-shaped groove. Although the groove 26 shown in FIG. 3 is V-shaped, the groove 26 could be square, rectangular or curved. The groove 26 may be formed by methods other than cutting, such as etching. The mold compound 34 is formed in the groove 26 preferably by injection during an injection molding process.

Referring now to FIG. 5, an enlarged, top, plan view of a wafer 40 having the plurality of integrated circuits 22 formed thereon is shown. The wafer 40 and the circuits 22 are of a type known to those of ordinary skill in the art and the present invention is not limited to any particular wafer or circuit. The circuits 22 are formed on a top surface of the wafer 40 and have a plurality of bonding pads thereon. Typically the bonding pads are formed around the perimeters of the top surfaces of the circuits 22.

FIG. 6 is an enlarged view of a portion of the wafer 40 in which the individual circuits 22 are being separated from each other and a plurality of the grooves 26 are being formed in the bottom surface of the wafer 40, beneath the circuits 22, such that each of the circuits 22 has at least one groove 26 extending along its bottom surface. In the presently preferred embodiment, the grooves 26 are V-shaped and are formed by sawing with a V-shaped blade 42. The grooves 26 preferably are formed in the wafer 40 prior to separating the ICs 22 from each other. FIG. 6 also illustrates the IC separating step, which is done using a known sawing process, using a saw blade 44.

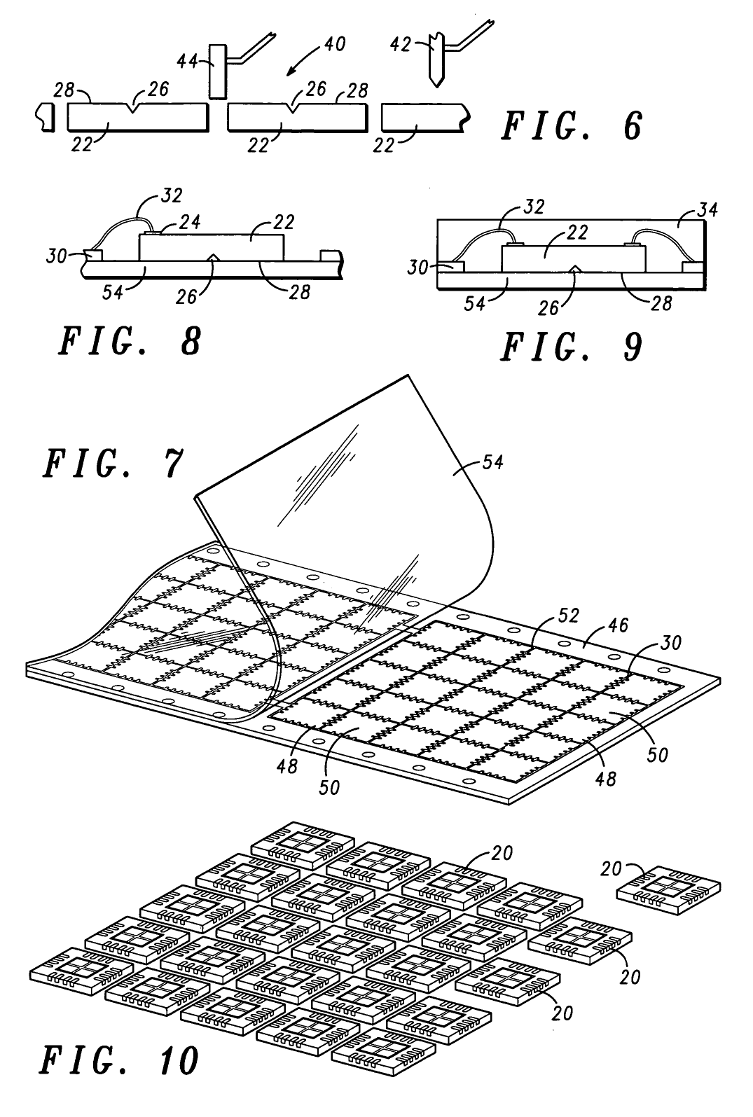

FIG. 7 is an enlarged perspective view of a leadframe panel 46 having a plurality of leadframes 48 connected together with connection bars 52. In the embodiment shown, the leadframe panel 46 comprises a 5×5 matrix of the leadframes 48. However, the leadframe panel 46 may have more or fewer of the leadframes 48. Alternatively, the leadframes 48 could be supplied on a strip. Both leadframe panels and leadframe strips are known by those of skill in the art. Each of the leadframes 48 has a perimeter (i.e. the connection bars 52) that defines a cavity or die receiving area 50 and a plurality of lead fingers 30 extending inwardly from the perimeter. The size and shape, as well as the number of leads 30, of the leadframes 48 are determined based on the size, shape and number of bonding pads of the ICs 22. Although the lead fingers 30 generally are the same length and width, the lead fingers 30 may vary in length and width. For example, lead fingers used for power and ground may be wider than signal leads. The leadframe panel 46 is preferably formed of a metal or metal alloy and has a predetermined thickness. In the presently preferred embodiment, the leadframe panel 46 is formed of copper that is pre-plated with tin. The leadframe panel 46 may be formed by cutting, stamping or etching as known by those of skill in the art.

A piece of tape 54 is applied to a first side of the leadframe panel 46. The tape 54 is of a type known to those of skill in the art typically used in semiconductor packaging operations that can withstand high temperatures. The tape 54 has an adhesive or glue on one side that allows it to stick to the leadframe panel 46. The integrated circuits 22 having at least one groove 26 are placed in the die receiving areas 50 of the leadframes 48 using a commercially available pick and place machine. Referring to FIG. 8, as can be seen the integrated circuits 22 are placed with their bottom surfaces 28 against the tape 54 and as the tape 54 has an adhesive thereon, the circuits 22 stick to the tape 54. That is, a bottom surface 28 of the integrated circuit 22 adheres to the glue or adhesive of the tape 54. The die receiving areas 50 are sized and shaped depending on the size and shape of the integrated circuit 22. For example, if the circuit 22 is rectangular, then it is preferred that the die receiving area 50 is rectangular too. The die receiving area 50 is slightly larger than the circuit 22.

After the leadframe panel 46 is populated with integrated circuits 22, the bonding pads 24 of the circuits 22 are electrically connected to the lead fingers 30 of the lead frames 48. The bonding pads 24 and lead fingers 30 preferably are connected with wires 32 using a known wirebonding process. The wires 32 are wires suitable for wirebonding, such as those composed of gold or copper. Various diameter wires may be used depending on the number of circuit I/Os and the size of the device 20.

Referring now to FIG. 9, a molding operation is performed for forming a mold compound 34 over the integrated circuit 22, the wires 32, and a portion of the lead fingers 30. The lead frame panel 46 may be etched at predetermined intervals to allow the mold compound 34 to be injected into the grooves 26. The mold compound 34 may comprise a plastic as is commonly used in packaged electronic devices. The tape 54 protects the bottom surface 28 of the integrated circuit 22 and the leadframes 48 from mold resin bleeding.

After the molding operation is completed, the tape 54 is removed from the leadframe panel 48 such that the first sides of the lead fingers 30 and the bottom sides 28 of the integrated circuits 22 are exposed. The tape 54 may be removed manually or with automated equipment that is presently commercially available.

The leadframes 48 are separated from each other by performing a dicing or singulation operation, as shown in FIG. 10, to form the individual packaged devices 20. The dicing operation also causes the outer sides of the lead fingers 30 to be exposed. Dicing and saw singulation processes are well known in the art.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A semiconductor device, comprising:
an integrated circuit (IC) having a plurality of bonding pads located on a peripheral portion of a first surface thereof and a groove formed in a second surface thereof, the groove extending from one end of the IC to an opposite end of the IC;
a plurality of lead fingers surrounding the IC;
a plurality of wires connecting the IC bonding pads with respective ones of the plurality of lead fingers; and
a mold compound covering the first surface of the IC, the plurality of wires, and a portion of the plurality of lead fingers, wherein at least bottom surfaces of the leads fingers and the second surface of the IC are exposed, and wherein the groove is filled with the mold compound.

2. The semiconductor device of claim 1, wherein the wires are connected to the IC bonding pads and the lead fingers with a wirebonding process.

3. The semiconductor device of claim 1, wherein a depth of the groove is less than a thickness of the lead fingers.

4. The semiconductor device of claim 3, wherein the groove has a depth of about 3 mils.

5. The semiconductor device of claim 1, wherein the groove is formed in the second surface of the IC with a sawing process.

6. The semiconductor device of claim 5, wherein the groove is V-shaped.

7. The semiconductor device of claim 1, wherein the groove comprises at least two grooves extending across the IC.

8. The semiconductor device of claim 7, wherein the groove comprises two grooves that intersect near a center of the IC.

9. A semiconductor device, comprising:
an integrated circuit (IC) having a plurality of bonding pads located on a peripheral portion of a first surface thereof;
a plurality of lead fingers surrounding the IC;
means for electrically connecting the IC bonding pads with respective ones of the plurality of lead fingers;
a mold compound covering the first surface of the IC, the electrical connecting means, and a portion of the plurality of lead fingers, wherein at least bottom surfaces of the lead fingers and a second surface of the IC are exposed; and
means for inhibiting a separation of the IC from the mold compound.

10. The semiconductor device of claim 9, wherein the means for electrically connecting the IC bonding pads with the lead fingers comprises a corresponding plurality of wires.

11. The semiconductor device of claim 10, wherein the wires are connected to the IC bonding pads and the lead fingers with a wirebonding process.

12. The semiconductor device of claim 9, wherein the means for inhibiting comprises a groove formed in the second surface of the IC, wherein the groove is filled with the mold compound.

13. The semiconductor device of claim 12, wherein the groove is formed in the second surface of the IC with a sawing process.

14. The semiconductor device of claim 13, wherein the groove is V-shaped.

15. The semiconductor device of claim 12, wherein the groove comprises at least two grooves extending across the IC.

16. The semiconductor device of claim 15, wherein the two grooves intersect near a center of the IC.

17. A method of packaging a semiconductor device, comprising the steps of:
providing a wafer having a plurality of integrated circuits (ICs) formed on a first surface thereof, wherein the ICs have a top surface with a plurality of bonding pads and a bottom surface;
forming a plurality of grooves in a second surface of the wafer such that each of the ICs has at least one groove extending along a bottom surface thereof;
separating the ICs from each other;
providing a leadframe panel having a plurality of leadframes, each of the leadframes having a plurality of lead fingers formed around a die receiving area;
applying a tape to a first side of the leadframe panel;
attaching the bottom surfaces of the separated ICs to the tape in respective ones of the die receiving areas;
electrically connecting the IC bonding pads with respective ones of the lead fingers;
forming a mold compound over at least a second surface of the leadframe panel such that the mold compound covers the top surface of the IC, the electrical connections, and the second side of the lead fingers;
injecting the mold compound into the grooves in the bottom surfaces of the ICs;
removing the tape from the first side of the lead frame panel such that the first sides of the lead fingers and the bottom sides of the ICs are exposed.

18. The method of packaging a semiconductor device of claim 17, further comprising the step of separating the leadframes from each other.

19. The method of packaging a semiconductor device of claim 17, wherein the grooves are formed in the wafer by sawing a plurality of V-shaped channels in the wafer.
